(19) United States
(12) Patent Application Publication
(10) Pub. No.: US 2026/0255519 A1
(43) Pub. Date: Aug. 27, 2026

(54) ROTARY AUXILIARY POSITIONING HANDLE ASSEMBLY

(71) Applicant: HANWIT PRECISION INDUSTRIES LTD., New Taipei (TW)

(72) Inventors: Ying-Chih TSENG, New Taipei (TW); Ming-De WU, New Taipei (TW)

(21) Appl. No.: 19/065,622

(22) Filed: Feb. 27, 2025

(51) Int. Cl. H05K 7/14

(52) U.S. Cl. CPC H05K 7/1402

(57) ABSTRACT

A rotary auxiliary positioning handle assembly includes a base frame having an assembly space and an extension side adjacent to each other and two opposite buckle portions at the assembly space, an auxiliary frame reciprocatably mounted on the extension side, and a driving handle assembled at the assembly space with two buckles on one side thereof and exposed to the outside of the assembly space and a lock on an opposite side thereof movably disposed at the buckle portions. By turning the driving handle and then rotating it, the base frame and the auxiliary frame can be driven to rotate and move.

### BACKGROUND OF THE INVENTION

### 1. Field of the Invention

The present invention provides a rotary auxiliary positioning handle assembly, in particular a positioning handle assembly that can be locked or unlocked by turning a driving handle. An auxiliary frame is assembled with the driving handle on a base frame. By turning the driving handle and using a hook member on one side of the auxiliary frame as a fulcrum, the base frame can be smoothly rotated and swung to achieve the purpose of locking or unlocking.

### 2. Description of the Related Art

With the continuous progress and development of electronic technology, computer technology has brought people convenience, comfort, speed and other high-efficiency functions in life and work. Therefore, the application functions of electronic technology, computer systems, etc. are becoming increasingly powerful and their scope is becoming increasingly wider. In addition to general personal computers, there are also centrally controlled operations through central processing systems, such as industrial computer rooms, building central control systems, central control systems for automated factory operation systems, central processing control systems for audio and video playback, etc., which are all connected to multiple computer hosts, servers, and operation conversion through centralized management. Device cases are assembled in a stacked manner inside a large electronic equipment cabinet, and the device cases can be pulled out or pushed from the side of the electronic equipment cabinet to assemble or repair various computer operating systems, etc. The device cases can also be combined with multiple operating host systems. When various computer operating systems need to be tested, updated, or other related operations, the device cases of different layers must be pulled out of the electronic equipment cabinet one by one to facilitate testing or related maintenance operations. Therefore, many stacked device cases assembled in the electronic equipment cabinet are provided with simple buckling structures, so that each device case can be easily assembled into the cabinet or pulled out from the cabinet by the buckling structures.

The stacked device cases assembled inside the electronic equipment cabinet are equipped with various electronic and circuit systems. In addition to being able to perform general word processing and application program execution, they can also connect to the Internet to search for a lot of information. As a result, computers occupy a very important position in our daily life and work. In addition to the related peripheral devices, each device case will also be equipped with a removable slot space to facilitate the expansion of data storage and the preservation and confidentiality of data. It can be used to easily plug in a removable hard drive, and can also be used to electrically plug in electronic devices such as optical disc drives or multimedia players. That is, it does not occupy the host space of each device case and can still effectively expand the application mode. However, the slot space provided in the host of each device case is a slot frame space formed by a fixed frame. When utilizing the slot space to plug in electronic products, the assembly path or space is often blocked or restricted by handles disposed outside the device case. In order to meet assembly requirements, the electronic devices must be threaded with various cables. However, the design of each device case is not conducive to the threading of the cables. As a result, the cables are exposed outside the device case and are easily pulled when the case is plugged in or out. It is not only unsightly but also affects the safety of the cables, causing inconvenience in plugging in and out electronic products with the host inside the device case, which needs to be improved.

Therefore, how to solve the inconvenience and trouble of pulling out and pushing the device cases inside the electronic equipment cabinet, and the problem that the handles on the device cases that can be pulled out easily block the paths and spaces for assembling the electronic circuits inside the device cases and the external electronic products, and make it difficult to run the wires because the device cases are arranged side by side or stacked, these are the directions that the relevant manufacturers engaged in this industry are eager to study and improve.

### SUMMARY OF THE INVENTION

Therefore, in view of the above problems and deficiencies, the inventor collected relevant information, conducted multiple evaluations and considerations, and based on his many years of experience in this industry, through continuous creation, research and improvement, he finally designed the invention patent of this rotary auxiliary positioning handle assembly.

The main object of the present invention is to provide a rotary auxiliary positioning handle assembly, which comprises a base frame comprising an assembly space and an extension side adjacent to each other and two buckle portions at two opposite sides of the assembly space, an auxiliary frame assembled at the inner side of the assembly space and the extension side of the base frame and be able to recoprovate along the extension side and comprising a hook member provided on one side thereof to expose to the outside of the extension side, and a driving handle assembled at the assembly space of the base frame and comprising two buckles on one side thereof and exposed to the outside of the assembly space and a lock on an opposite side thereof to be movably disposed at the buckle portions of the base frame. The base frame and the auxiliary frame can be driven to rotate and move by turning then rotating and swinging the driving handle, so that the driving handle can be used to lock or unlock.

Another object of the present invention is that the assembly space of the base frame is recessed, the extension side adjacent to the assembly space is L-shaped, and the buckle portions of the base frame are convex and hook-shaped and are provided on the two opposite sides of the assembly space for the lock of the driving handle to be movably engaged; the base frame further comprises a sliding space concavely provided adjacent to the buckle portions; the base frame further comprises two coupling members respectively provided at two opposite outer sides of the assembly space and the extension side, and a cover plate covering the auxiliary frame and the extension side for applying force to open.

Still another object of the present invention is that the auxiliary frame further comprises at least one oblong elliptical shaped slide groove, a wing plate provided on one side thereof for assembling the hook member, and a sliding groove provided on the wing plate for a connecting member to pass through so as to movably assemble the hook member; the base frame further comprises at least one pivot hole on the side thereof opposite to the at least one slide groove for pivotally assembling a pivot member at the corresponding at least one slide groove, a guide groove provided on the extension side adjacent to the sliding groove of the wing plate; the hook member of the auxiliary frame is provided with a limit rod for sliding at the guide groove.

Still another object of the present invention is that the driving handle further comprises a push space on one concave side thereof for assembling the lock, two suspended arm plates respectively extending along two sides of the push space, two L-shaped side plates respectively located between the two suspended arm plates on two opposite sides of the lock, an oblong elliptical slide groove provided at each of two side plates, a stopper shaft provided at the two suspended arm plates to allow the slide grooves of the two side plates to move, and two clamping grooves formed between the two suspended arm plates and the two side plates for the buckle portions at the two opposite sides of the assembly space of the base frame to be embedded.

Still another object of the present invention is that the two buckle portions are transversely located at two opposite sides of the assembly space of the base frame; the two clamping grooves are transversely formed between the two suspended arm plates and the two side plates of the lock of the driving member for the two buckle portions at the two opposite sides of the assembly space of the base frame to be movably slidably engaged and locked or released by the two clamping grooves.

Still another object of the present invention is that the buckles of the driving handle are Y-shaped; the driving handle further comprises two axle holes bilaterally provided near the buckles, two notches respectively provided on the buckles; the auxiliary frame further comprises a limit wing provided on one side thereof relative to the axle holes, and a limit groove provided at the limit wing; the base frame further comprises two axle holes respectively provided at two opposite sides of the assembly space relative to the axle holes of the driving handle, and two shafts provided to respectively pivot the axle holes of the buckles to the axle holes of the base frame and the loimit groove, so that the driving handle can be rotated axially with each shaft as the axis relative to the axle holes of the two buckles.

### BRIEF DESCRIPTION OF THE DRAWINGS

FIG. 1 is a three-dimensional external view of the present invention.

FIG. 2 is a three-dimensional external view of the present invention from another viewing angle.

FIG. 3 is a three-dimensional exploded view of the present

FIG. 4 is a three-dimensional exploded view of the present invention from another viewing angle.

FIG. 5 is a three-dimensional exploded view of a preferred embodiment of the present invention.

FIG. 6 is a three-dimensional exploded view of a preferred application embodiment of the present invention.

FIG. 7 is a three-dimensional external view of a preferred application embodiment of the present invention.

FIG. 8 is a top view of the preferred embodiment of the present invention before unlocking.

FIG. 9 is a sectional top view of a preferred embodiment of the present invention before unlocking.

FIG. 10 is a top view of the preferred embodiment of the present invention when unlocked.

FIG. 11 is a sectional top view of the preferred embodiment of the present invention when unlocked.

FIG. 12 is a top view of the preferred embodiment of the present invention after unlocking.

FIG. 13 is a sectional top view of the preferred embodiment of the present invention after unlocking.

### DETAILED DESCRIPTION OF THE PREFERRED EMBODIMENT

In order to achieve the above-mentioned object and effect, the technical means and structure, implementation method, etc. adopted by the present invention are now described in detail with reference to the annexed drawings for the preferred embodiment of the present invention, and its features and functions are as follows, so as to facilitate a complete understanding.

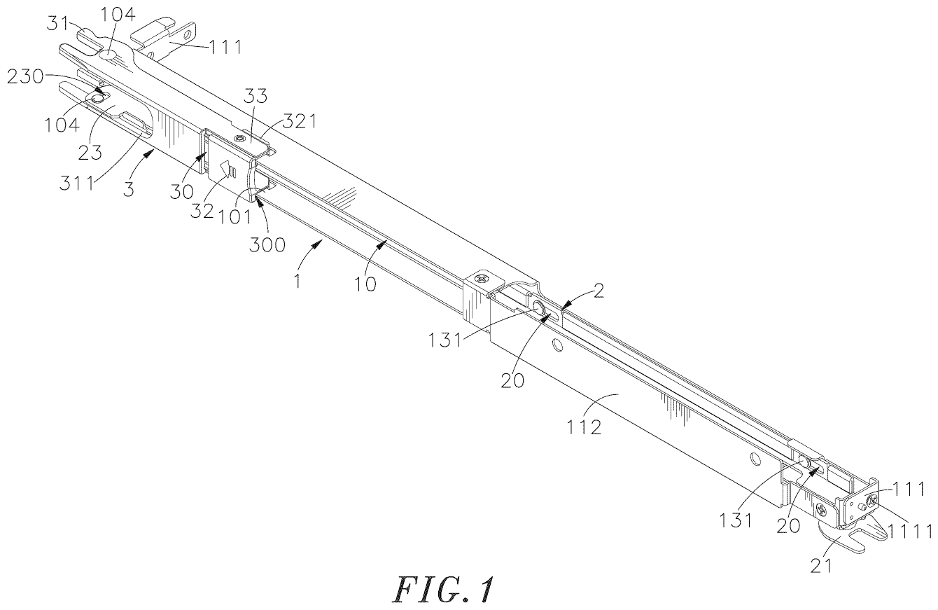

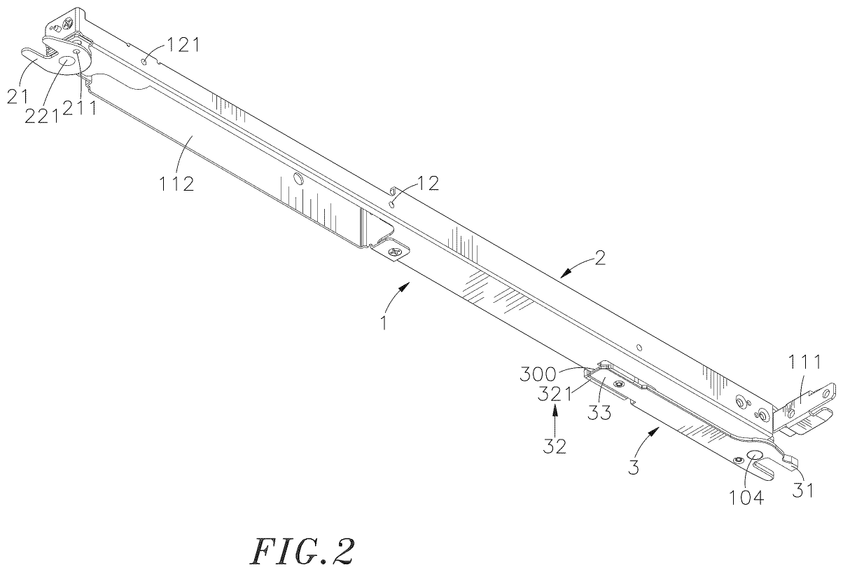

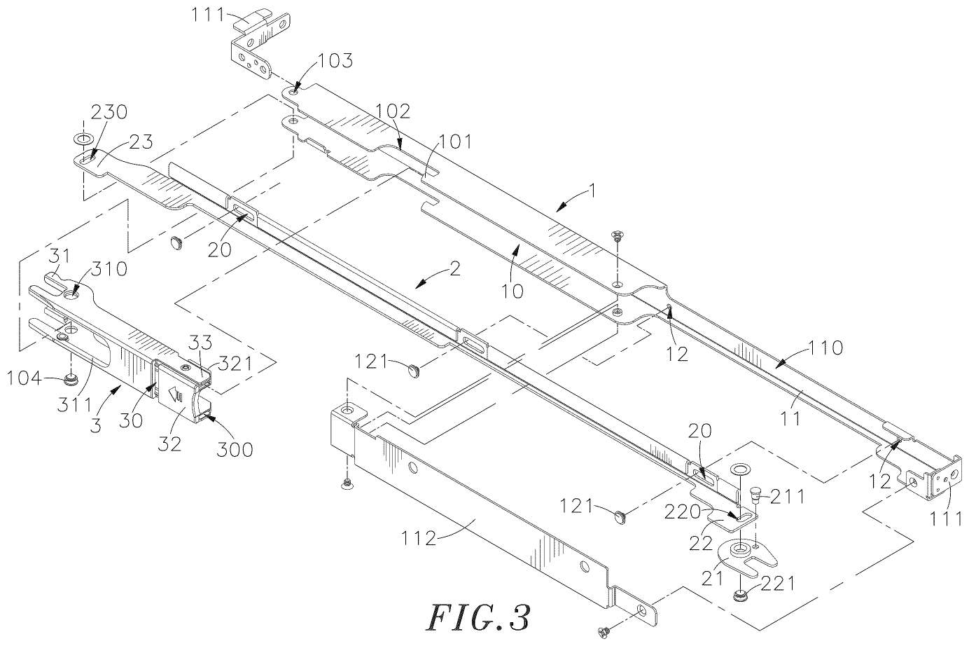

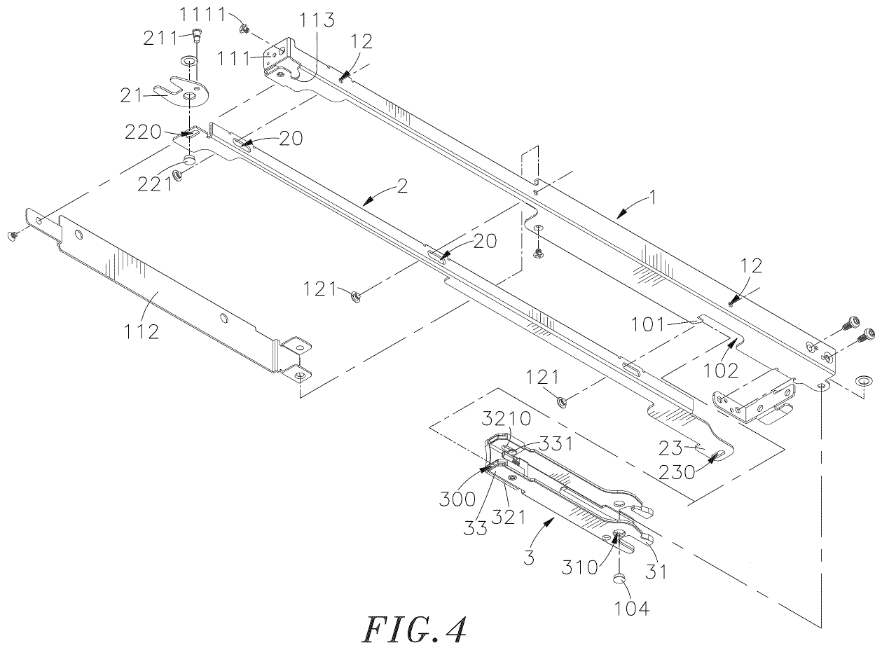

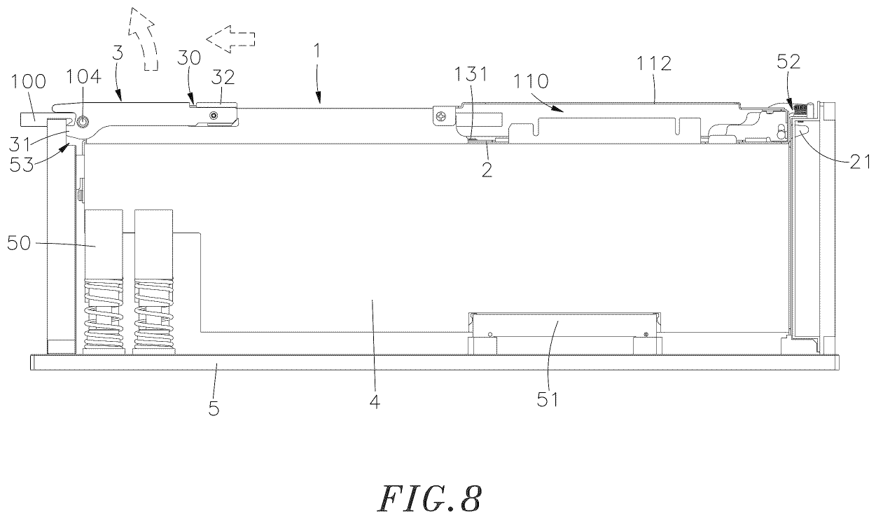

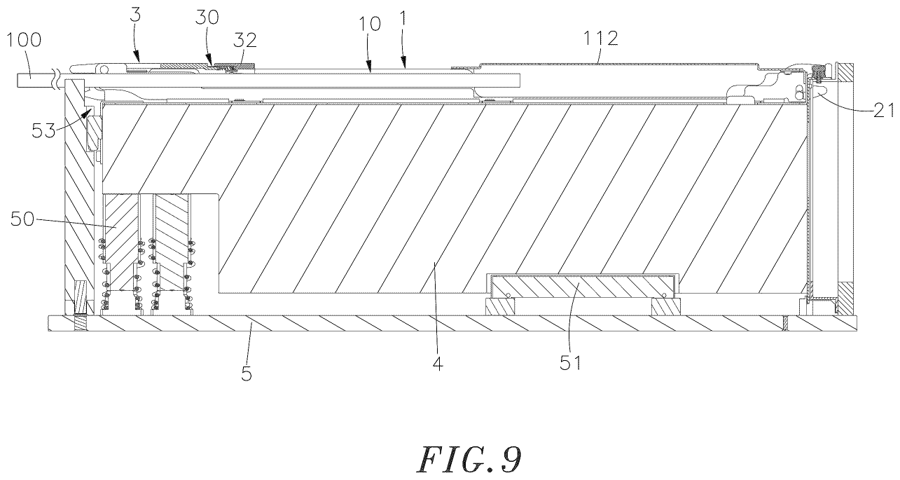

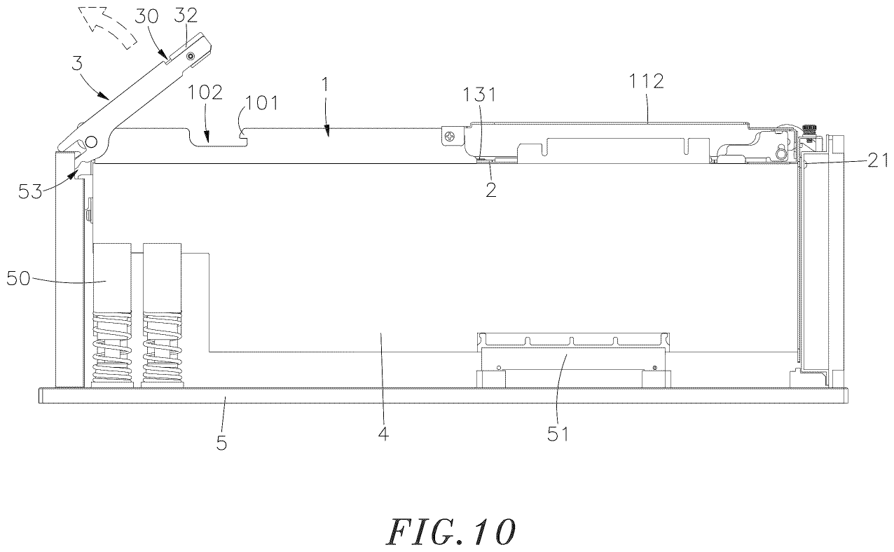

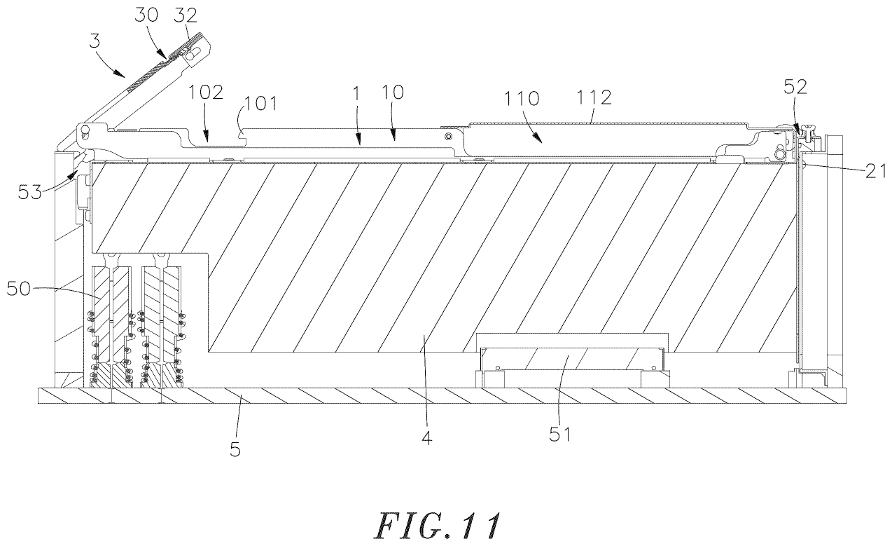

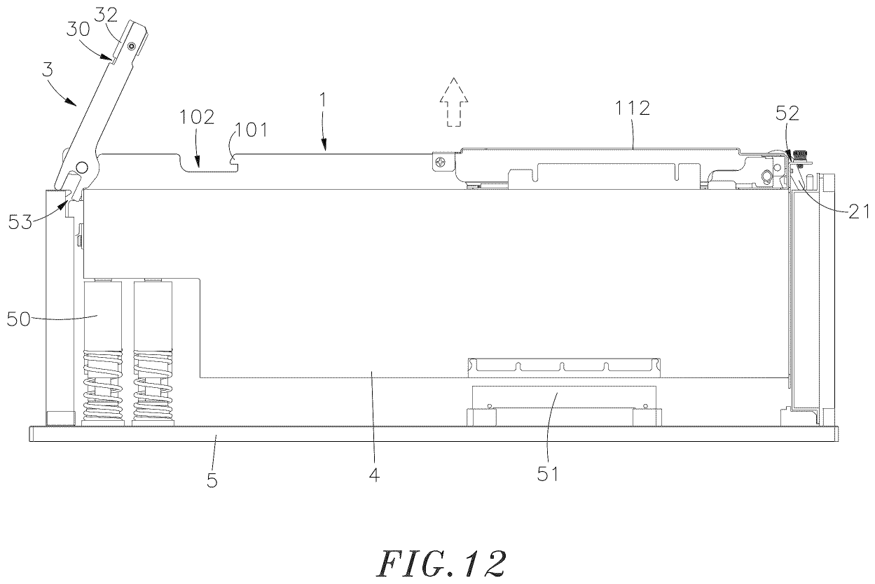

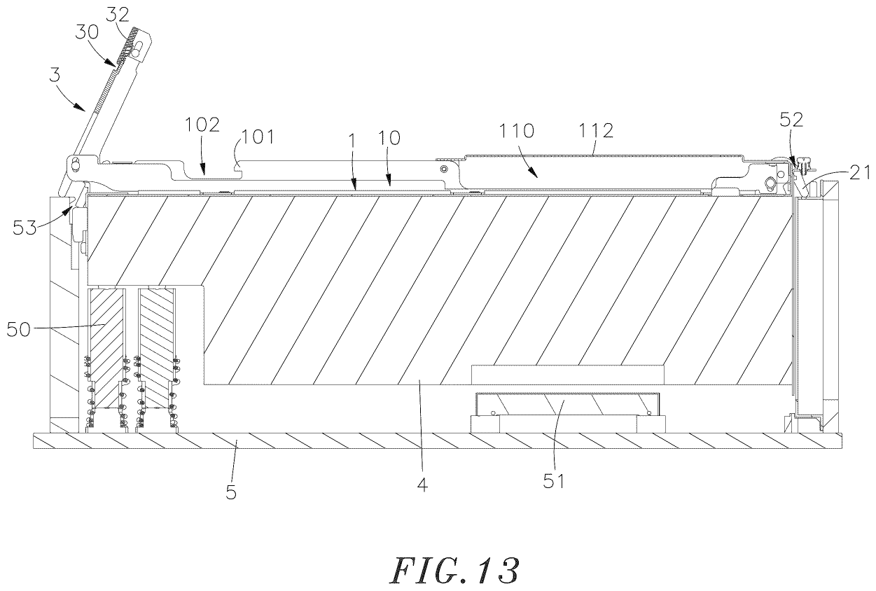

Please refer to FIGS. 1 to 13, the rotary auxiliary positioning handle assembly of the present invention comprises a base frame 1, an auxiliary frame 2, and a driving handle 3.

The base frame 1 comprises an assembly space 10 and an extension side 11 adjacent to each other, and two buckle portions 101 transversely located at two opposite sides of the assembly space 10.

The auxiliary frame 2 is assembled at the inner side of the assembly space 10 and the extension side 11 of the base frame 1 so that the auxiliary frame 2 can reciprocate along the extension side 11. A hook member 21 is provided on one side of the auxiliary frame 2 to expose to the outside of the extension side 11.

The driving handle 3 is assembled at the assembly space 10 on the other side of the base frame 1. The driving handle 3 comprises two buckles 31 on one side thereof and exposed to the outside of the assembly space 10, a lock 32 on the other side thereof that is movably disposed at the buckle portions 101, and two transverse U-shaped notches 311 provided adjacent to the buckles 31.

The above-mentioned base frame 1 of the present invention is provided with a recessed assembly space 10, an L-shaped extension side 11 is provided one side thereof adjacent to the assembly space 10, and two relatively convex and hook-shaped buckle portions 101 are provided on the sides of the assembly space 10, and a sliding space 102 is concavely provided adjacent to the buckle portions 101. The assembly space 10 of the base frame 1 and the inner side opposite to the driving handle 3 are used to pass the preset wires 100 (which may be cables, transmission lines or power lines, etc.) to prevent the preset wires 100 from being exposed and to protect the preset wires 100 from being pulled or disturbed by external forces. The assembly space 10 and the extension side 11 of the base frame 1 are provided with coupling members 111 at two opposite outer sides, and the auxiliary frame 2 and the extension side 11 are covered with a cover plate 112 to form a swing space 110 between the cover plate 112 and the auxiliary frame 2 and the extension side 11. The swing space 110 can be opened by applying force toward the cover plate 112 to facilitate the assembly of the base frame 1.

The above-mentioned auxiliary frame 2 of the present invention is provided with at least one oblong elliptical shaped slide groove 20, and at least one pivot hole 12 is provided on the side of the base frame 1 opposite to the slide groove 20 for pivotally assembling a pivot member 121 at the corresponding at least one slide groove 20. A wing plate 22 is provided on one side of the auxiliary frame 2 for assembling the hook member 21, and a sliding groove 220 is provided on the wing plate 22 for a connecting member 221 to pass through so as to movably assemble the hook member 21. A guide groove 113 is further provided on the extension side 11 adjacent to the sliding groove 220, and a limit rod 211 is provided on the hook member 21 for sliding at the guide groove 113. A limit wing 23 is provided on the other side of the auxiliary frame 2 opposite to the wing plate 22, and a long-shaped limit groove 230 is provided at the limit wing 23.

Furthermore, the above-mentioned driving handle 3 of the present invention comprises a push space 30 on one concave side for assembling the lock 32, and the push space 30 has two sides extending with suspended arm plates 33, and the lock 32 has two side plates 321 on the two sides, and the two side plates 321 are relatively L-shaped and are respectively located between the two suspended arm plates 33. The oblong elliptical slide grooves 3210 are provided at the two side plates 321. A stopper shaft 331 is provided at the two suspended arm plates 33 to allow the slide grooves 3210 of the two side plates 321 to move. Two clamping grooves 300 are formed between the two suspended arm plates 33 and the two side plates 321 for the buckle portions 101 at the two opposing sides of the assembly space 10 of the base frame 1 to be embedded.

The above-mentioned base frame 1 of the present invention may be provided with two buckle portions 101 transversely facing each other in the upper and lower directions at the sides of the assembly space 10, and two clamping grooves 300 transversely facing each other in the upper and lower directions are also provided between the two side plates 321 of the lock 32 and the two suspended arm plates 33 of the driving handle 3, so that the two clamping grooves 300 transversely facing each other in the upper and lower directions can slide relative to each other between the two buckle portions 101 in the form of buckle locking or release.

In addition, the above-mentioned driving handle 3 of the present invention may be provided with two Y-shaped buckles 31 on one side, that is, two axle holes 310 may be provided near the buckles 31, and a limit wing 23 may be provided on one side of the auxiliary frame 2 relative to the axle holes 310, and a limit groove 230 may be provided at the limit wing 23. Relative to the axle holes 310, two axle holes 103 are respectively provided at two opposite sides of the assembly space 10 on one side of the base frame 1 and a limit groove 230 is provided at the limit wing 23 on one side of the auxiliary frame 2, and two shafts 104 are provided to respectively pivot the axle holes 310 of the buckles 31 to the axle holes 103 of the base frame 1 and the limit groove 230, so that the driving handle 3 can be axially rotated relative to each axle hole 103 and the limit groove 230 with each shaft 104 as the axis through the axle holes 310 of the two buckles 31.

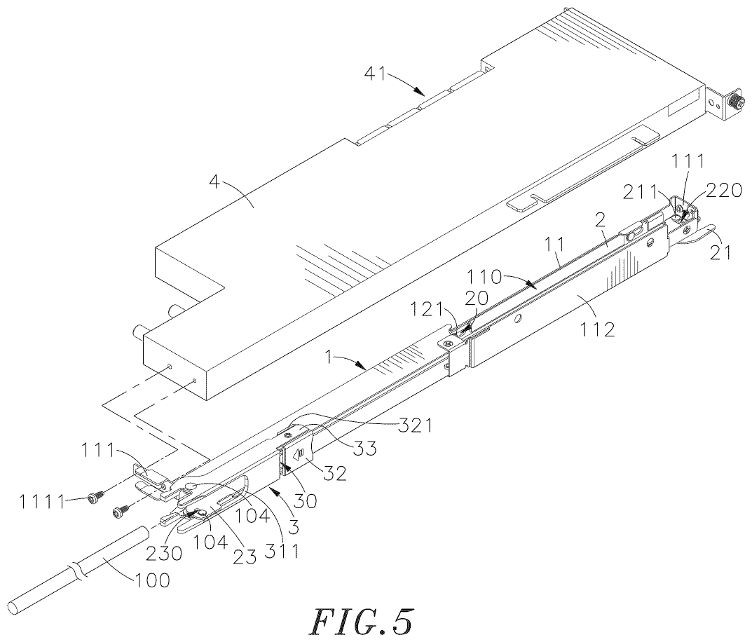

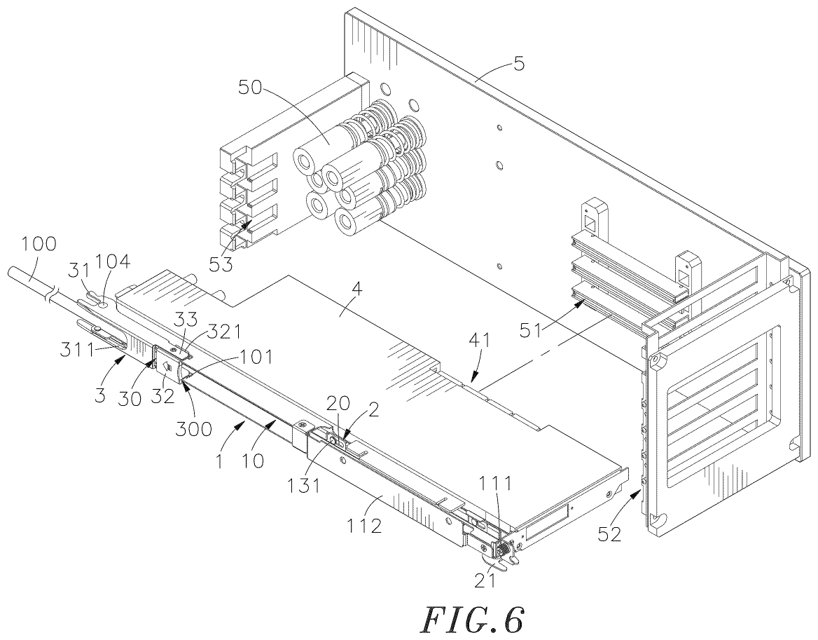

When the rotary auxiliary positioning handle assembly of the present invention is actually applied and implemented, please refer to FIGS. 5 to 13 at the same time, where the base frame 1, the auxiliary frame 2 and the driving handle 3 of the present invention can be assembled on a preset electronic device 4, which can be a hard disk, a multimedia audio-visual device (such as CD drive, DVD drive or card reader, etc.), server cabinet, a computer mainframe circuit board or any of various interface cards, etc. The coupling members 111 on both sides of the base frame 1 can be assembled and fixed to the preset electronic device 4 by using fixing members 1111 (which can be screws, rivets or pins, etc.), and the preset electronic device 4 can be assembled to the preset electronic case 5 (which can be a computer case, a server cabinet, an electrical case or an industrial computer case, etc.) by using the base frame 1 (please refer to FIGS. 5 and 6 at the same time), so that the connection interface 41 of the preset electronic device 4 and the docking interface 51 of the preset electronic case 5 are electrically connected (the connection interface 41 and the docking interface 51 can be respective electrical connectors). The hook member 21 of the auxiliary frame 2 on one side of the base frame 1 and the buckles 31 of the driving handle 3 on the other side can be assembled and buckled at the first buckle portion 52 and the second buckle portion 53 on the preset electronic case 5, so that the driving handle 3 can be aligned with the water cooling connector 50 provided on the preset electronic case 5. Thus, the preset electronic device 4 can be assembled on the preset electronic case 5 (please also refer to FIGS. 6 to 9), so as to achieve the purpose of assembling the preset electronic device 4 on the preset electronic case 5 conveniently.

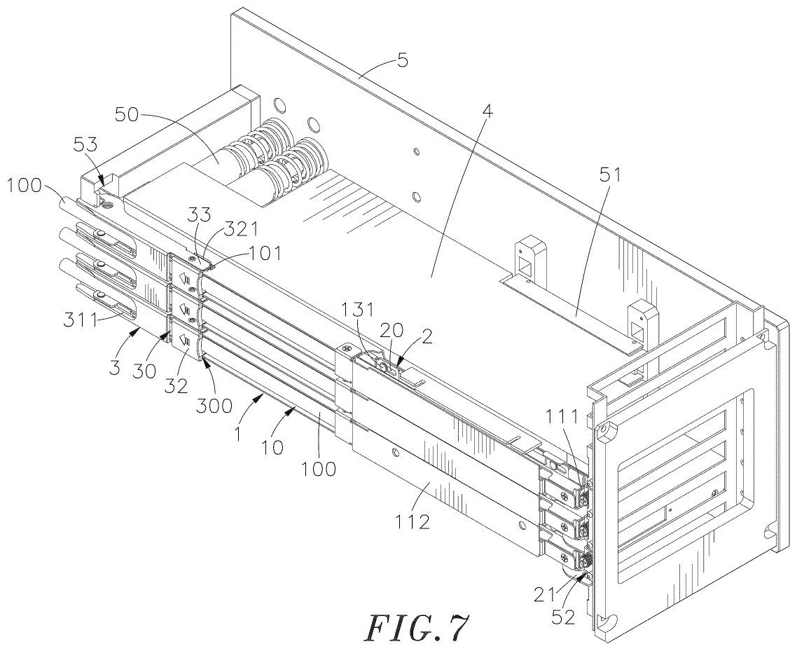

Please refer to FIGS. 7 to 13, when removing the preset electronic device 4 from the preset electronic case 5, the driving handle 3 assembled in the assembly space 10 on one side of the base frame 1 can be operated to move the lock 32 of the driving handle 3 to the other side of the sliding space 102 away from the two buckle portions 101, so that the two clamping grooves 300 at the lock 32 are respectively withdrawn from the outside of the two buckle portions 101. The buckles 31 slide on the long-shaped limit groove 230 of the limit wing 23 through the shafts 104 pivoted by the axle holes 310, forming a longitudinal and transverse buffer zone. When the driving handle 3 is pulled at the preset electronic case 5, a buffering effect of vertical height difference or horizontal deviation is formed, making it easier for the driving handle 3 to drive the base frame 1, the auxiliary frame 2 and the preset electronic device 4 to withdraw from the preset electronic case 5. Then apply force to open and pull the driving handle 3 toward the outside of the base frame 1, so that the Y-shaped buckles 31 on one side of the driving handle 3 can be removed from the second buckle portion 53 of the preset electronic case 5. The notches 311 on one side of the buckle 31 are used to form a space to avoid the preset wires 100, so that the opening of the driving handle 3 does not interfere with the setting of the preset wires 100. At the same time, apply force to the swing space 110 at the extension side 11 and the cover plate 112 to pull toward the cover plate 112, so that the limit rod 211 on the hook member 21 on one side of the auxiliary frame 2 can slide along the sliding groove 220. At the same time, the hook member 21 rotates and swings with the connecting member 221 as the axis and swings along the guide groove 113 on the extension side 11, so that the hook member 21 can exit the first buckle portion 52 on one side of the preset electronic case 5, so as to use the driving handle 3 and the cover plate 112 on both sides of the base frame 1 to withdraw the preset electronic device 4 from the preset electronic case 5 without interfering with the layout of the preset wires 100. The connection interface 41 and the docking interface 51 are also separated, so that the preset electronic device 4 can be smoothly and quickly taken out from the preset electronic case 5, thereby achieving the purpose of the driving handle 3 driving the base frame 1 and the auxiliary frame 2 to rotate and move, and the driving handle 3 forms a locking or unlocking function.

The above is merely a preferred embodiment of the present invention and is not intended to limit the patent scope of the present invention. Therefore, all simple modifications and equivalent structural changes made by using the contents of the description and drawings of the present invention should be included in the patent scope of the present invention and should be declared.

In summary, the rotary auxiliary positioning handle assembly of the present invention can achieve its effect and purpose in actual application. Therefore, this invention is truly a research and development creation with excellent practicality. In order to meet the application requirements for invention patents, we have filed an application in accordance with the law. We hope that the review committee will approve this case as soon as possible to protect the inventor's hard work in research and development. If the review committee has any questions, please feel free to write to us for instructions. The inventor will do his best to cooperate and we will be grateful for your help.

What the invention claimed is:

1. A rotary auxiliary positioning handle assembly, comprising a base frame, an auxiliary frame and a driving handle, wherein:
said base frame comprises an assembly space and an extension side adjacent to each other, and two buckle portions on two opposite sides of said assembly space;
said auxiliary frame is assembled at an inner side of said assembly space and said extension side of said base frame so that said auxiliary frame can reciprocate along said extension side, said auxiliary frame comprising a hook member provided on one side thereof to expose to the outside of said extension side;
said driving handle is assembled at said assembly space of said base frame, said driving handle comprising two buckles on one side thereof and exposed to the outside of said assembly space and a lock on an opposite side thereof, said lock being movably disposed at said two buckle portions of said base frame.

2. The rotary auxiliary positioning handle assembly as claimed in claim 1, wherein said assembly space of said base frame is recessed, said extension side adjacent to said assembly space is L-shaped, and said two buckle portions of said base frame are convex and hook-shaped and are provided on the two opposite sides of said assembly space for said lock of said driving handle to be movably engaged; said assembly space defines with said driving handle a space for inserting preset wires; said base frame further comprises a sliding space concavely provided adjacent to said two buckle portions.

3. The rotary auxiliary positioning handle assembly as claimed in claim 2, wherein said driving handle further comprises a push space on one concave side thereof for assembling said lock, two suspended arm plates respectively extending along two sides of said push space, two L-shaped side plates respectively located between said two suspended arm plates on two opposite sides of said lock, an oblong elliptical slide groove provided at each of said two side plates, a stopper shaft provided at said two suspended arm plates to allow said slide grooves of said two side plates to move, and two clamping grooves formed between said two suspended arm plates and said two side plates for said two buckle portions at the two opposite sides of said assembly space of said base frame to be embedded.

4. The rotary auxiliary positioning handle assembly as claimed in claim 3, wherein said two buckle portions are transversely located at two opposite sides of said assembly space of said base frame; said two clamping grooves are transversely formed between said two suspended arm plates and said two side plates of said lock of said driving handle for said two buckle portions at the two opposite sides of said assembly space of said base frame to be movably slidably engaged and locked or released by said two clamping grooves.

5. The rotary auxiliary positioning handle assembly as claimed in claim 2, wherein said base frame further comprises two coupling members respectively provided at two opposite outer sides of said assembly space and said extension side, and a cover plate covering said auxiliary frame and said extension side for applying force to open.

6. The rotary auxiliary positioning handle assembly as claimed in claim 1, wherein said auxiliary frame further comprises at least one oblong elliptical shaped slide groove, a wing plate provided on one side thereof for assembling said hook member, and a sliding groove provided on said wing plate for a connecting member to pass through so as to movably assemble said hook member; said base frame further comprises at least one pivot hole on the side thereof opposite to said at least one slide groove for pivotally assembling a pivot member at the corresponding said at least one slide groove, a guide groove provided on said extension side adjacent to said sliding groove of said wing plate; said hook member of said auxiliary frame is provided with a limit rod for sliding at said guide groove.

7. The rotary auxiliary positioning handle assembly as claimed in claim 1, wherein said buckles of said driving handle are Y-shaped; said driving handle further comprises two axle holes bilaterally provided near said buckles, two notches respectively provided on said buckles; said auxiliary frame further comprises a limit wing provided on one side thereof relative to said axle holes, and a limit groove provided at said limit wing; said base frame further comprises two axle holes respectively provided at two opposite sides of said assembly space relative to said axle holes of said driving handle, and two shafts provided to respectively pivot said axle holes of said buckles to said axle holes of said base frame and said limit groove.
